(19) United States
(12) Patent Application Publication
(10) Pub. No.: US 2015/0144972 A1
(43) Pub. Date: May 28, 2015

(54) MATRIX LEADFRAME FOR LED PACKAGING

(71) Applicant: KONINKLIJKE PHILIPS N.V., EINDHOVEN (NL)

(72) Inventors: Chee Weng Soong, Eindhoven (NL); Paul Scott Martin, Eindhoven (NL); Tomonari Ishikawa, Eindhoven (NL)

(21) Appl. No.: 14/416,074

(22) PCT Filed: Jul. 16, 2013
(86) PCT No.: PCT/IB2013/055842

§ 371 Date: Jan. 21, 2015

Related U.S. Application Data
(60) Provisional application No. 61/674,883, filed on Jul. 24, 2012.

(51) Int. Cl. H01L 33/62; H01L 33/50; H01L 33/48; H01L 33/56

(52) U.S. Cl. CPC H01L 33/62; H01L 33/56; H01L 33/507; H01L 33/486; H01L 2933/0033; H01L 2933/0041; H01L 2933/005; H01L 2933/0066
USPC 257/88; 438/27

(57) ABSTRACT

A leadframe (610) is formed that simplifies the packaging of light emitting elements and/or eliminates the need for stress-inducing folding after encapsulation. In particular, the folding of the contact tabs (505, 506) for surface mounting is performed prior to the mounting and encapsulation of the light emitting elements on the leadframe. In an example embodiment, the leadframe may be formed so that an array, or matrix, of light emitting elements may be packaged during a single packaging process.

### FIELD OF THE INVENTION

This invention relates to the field of light emitting devices (LEDs), and in particular to the use of a pre-formed matrix leadframe to facilitate the packaging of light emitting devices.

### BACKGROUND OF THE INVENTION

Metallic leadframes are commonly used as a substrate for mounting and encapsulating light emitting elements and providing contacts for external connections to the light emitting element.

FIGS. 1A-1C illustrate a conventional LED metallic leadframe 110. The leadframe 110 is patterned with openings 120 that define a plurality of LED metal patterns 101, as illustrated in FIG. 1A. Each pattern 101 includes a surface area 115 for mounting a light emitting element, and a pair of contact pads 105, 106 for external coupling to the light emitting element. In this example embodiment, the surface area 115 in which the light emitting element 140 is to be situated (FIG. 1B) may be ‘dimpled’ or depressed, to serve as a reflecting cup for reflecting light emitted from the sides of the light emitting element 140 upward. Although four LED metal patterns 101 are illustrated, the leadframe 110 may include many such patterns 101.

In this example embodiment, the light emitting element 140 includes two electrodes, one on its lower surface, and the other on its upper surface. The mounting of the light emitting element 140 on the surface area 115 provides contact to one of the electrodes of the light emitting element 140, and a bond wire 145 provides contact to the other of the electrodes of the light emitting element, as illustrated in FIG. 1B. By removing the tie bars 130 indicated by the Xs in FIG. 2B, which connect the metal patterns 101 to the leadframe 110, two isolated metallic islands 150, 160 are produced. Each island 150, 160 includes a contact pad 105, 106 that is coupled to a corresponding electrode of the light emitting element 140. These islands 150, 160 are held in place by an encapsulant (not illustrated) as detailed further below.

FIGS. 2A-2K illustrate the use of the leadframe 110 in a conventional packaging process. Initially, the leadframe 110 is bent along two bend lines 210A, 210B illustrated in FIG. 2A. This bending results in the cross-sections of the leadframe 110 illustrated in FIGS. 2B and 2C. The contact area 115, which may be depressed, serves as a mount for the light emitting elements 140.

After the light emitting elements 140 are mounted and coupled to the leadframe 110, as illustrated in FIGS. 2D and 2E, the light emitting elements 140 and the upper portion of the leadframe 110 are encapsulated by an encapsulant 250, as illustrated in FIGS. 2F and 2G. In these figures, for ease of visibility and understanding, the light emitting elements 140 are drawn in an oversized form in the profile views; in most embodiments, the light emitting element 140 is wholly contained within the recess 115.

Typically, silicone is used as the encapsulant 250, and may include dyes, scattering particles, or wavelength conversion material, such as phosphors, that enhance or modify the light emitted through the encapsulant 250. The dome shape of the encapsulant 250 provides a hemispherical pattern to the light emitted from the encapsulated device; other shapes may be used to provide different emission patterns.

An advantage of the illustrated pattern in the leadframe 110 is that each of the cut points 130 (X) on the islands (150, 160 in FIG. 1C) lie in two parallel planes when the leadframe 110 is bent, as illustrated in FIG. 2H, which facilitates an efficient removal of these tie bars 130 (X). After removing the tie bars 130, the formed light emitting devices may be singulated by slicing 230 a portion of the encapsulant 250 between each light emitting device. The resulting singulated device is illustrated in FIG. 2I.

After singulation, the contact pads 105, 106 are folded outward along line 270, so that the pads 105, 106 lie parallel to the light emitting surface of the singulated device, as illustrated in FIGS. 2J and 2K, to facilitate mounting the device on a printed circuit board or other surface.

Although the above packaging process is fairly efficient, it requires quite a few steps, and the tie-bar removal and folding of the pads 105, 106 after the packaging may introduce stress fractures, thereby reducing the yield of the process. The tie-bar removal after encapsulation also exposes the remnants of the clipped electrodes that extend below the encapsulant.

Of particular note, the process is limited to a single row of devices being fabricated at the same time, which, in combination with the reduced yield caused by the post-encapsulation folding of the pads, substantially limits the efficiency of the process.

### SUMMARY OF THE INVENTION

It would be advantageous to provide a simpler process for packaging light emitting devices using a leadframe. It would advantage to reduce defects caused by folding the tabs of light emitting devices after encapsulation. It would be advantageous to increase the number of light emitting devices that can be packaged at the same time.

To better address one or more of these concerns, in an embodiment of this invention, a leadframe is formed that simplifies the packaging of light emitting elements and/or eliminates the need for stress-inducing folding after encapsulation. In particular, the folding of the contact tabs for surface mounting is performed prior to the mounting and encapsulation of the light emitting devices on the leadframe. In an example embodiment, the leadframe may be formed so that an array, or matrix, of light emitting elements may be packaged during a single packaging process.

In an example embodiment, the leadframe is folded along at least four fold lines to pre-form the leadframe such that the contact pads for the light emitting device lie in a plane that is parallel to the surface area for mounting the light emitting element. After this folding, the light emitting elements are mounted on the leadframe, coupled to the contact pads, then encapsulated. The leadframe is then sliced to provide individual encapsulated (packaged) light emitting devices that are suitable for mounting on a surface, such as a printed circuit board, via the contact pads. Because the folding is performed prior to the mounting and encapsulation of the light emitting element, the encapsulated light emitting element is not subject to the stresses associated with the folding of the leadframe.

Because the contact pads are pre-folded to lie in a common plane, the patterns for the light emitting devices may be arrayed in two dimensions, forming a matrix of LED metal patterns, thereby increasing the number of light emitting devices that may be packaged at the same time, compared to the single row of light emitting devices discussed above.

### BRIEF DESCRIPTION OF THE DRAWINGS

The invention is explained in further detail, and by way of example, with reference to the accompanying drawings wherein:

FIGS. 1A-1C illustrates an example prior art leadframe.

FIGS. 2A-2K illustrate an example prior art process for fabricating light emitting devices using a leadframe.

FIGS. 3A-3C illustrate an example leadframe for fabricating light emitting devices.

FIGS. 4A-4D illustrate an example process for fabricating light emitting devices using the leadframe of FIGS. 3A-3C.

FIG. 5 illustrates an example alternative leadframe for fabricating light emitting devices.

FIGS. 6A-6D illustrate an example leadframe and process for fabricating a matrix of light emitting devices.

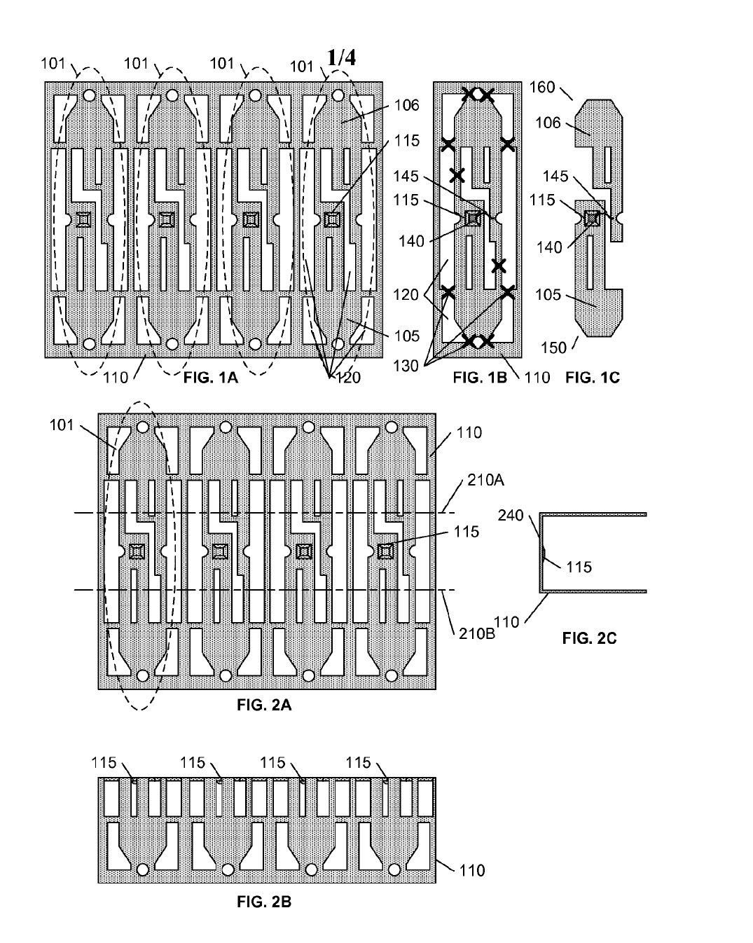

Throughout the drawings, the same reference numerals indicate similar or corresponding features or functions. The drawings are included for illustrative purposes and are not intended to limit the scope of the invention.

### DETAILED DESCRIPTION

In the following description, for purposes of explanation rather than limitation, specific details are set forth such as the particular architecture, interfaces, techniques, etc., in order to provide a thorough understanding of the concepts of the invention. However, it will be apparent to those skilled in the art that the present invention may be practiced in other embodiments, which depart from these specific details. In like manner, the text of this description is directed to the example embodiments as illustrated in the Figures, and is not intended to limit the claimed invention beyond the limits expressly included in the claims. For purposes of simplicity and clarity, detailed descriptions of well-known devices, circuits, and methods are omitted so as not to obscure the description of the present invention with unnecessary detail.

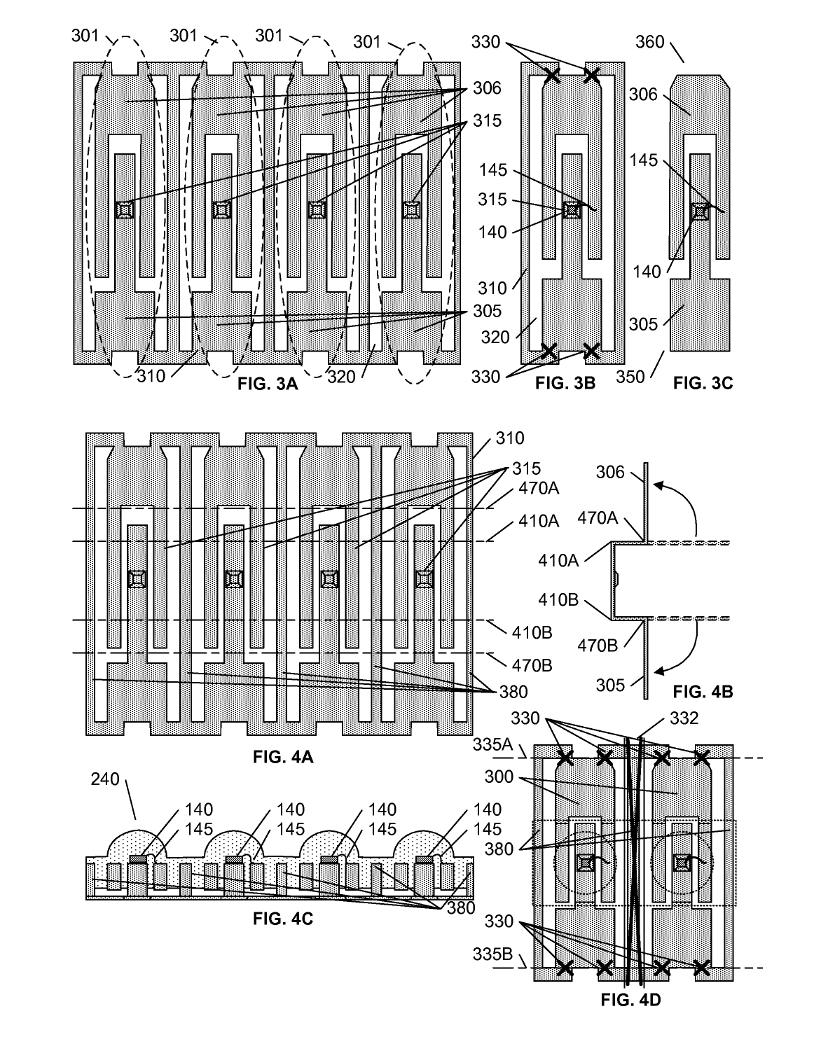

FIGS. 3A-3C illustrate an example leadframe for fabricating light emitting devices in accordance with an aspect of this invention. The leadframe 310 includes a pattern of openings 320 that define the resultant LED metal patterns 301, as illustrated in FIG. 3A. Each LED pattern 301 includes a surface area 315 for mounting a light emitting element, and contact pads 305, 306 for external coupling to the electrodes of the light emitting element. The surface area 315 may be depressed to form a reflecting cup.

In this example, the light emitting element 140 of FIG. 3B includes a contact electrode on its bottom surface, and a contact electrode on its upper surface (not illustrated). The mounting of the light emitting element 140 couples the bottom electrode to the leadframe 310 and a bond wire 145 couples the upper electrode to the leadframe 310. When the tie-bars at the Xs 330 are removed, two isolated metallic islands, 350, 360 are formed, with each contact pad 305, 306 connected to one of the electrodes of the light emitting element. It should be noted that leadframe 310 has fewer tie-bars than the prior art.

FIGS. 4A-4D illustrate an example process for fabricating light emitting devices using the leadframe of FIGS. 3A-3C. After the optional depressions are formed in the surface area 315, typically by stamping, the leadframe 310 is folded along fold-lines 410A-B and 470A-B, providing the ‘top-hat’, or ‘derby’ profile illustrated in FIG. 4B. The leadframe 310 may also be stamped or otherwise prepared to create creases or other features that facilitate this folding. Typically, the folding is performed sequentially. For example, the folding sequence may be 470A-410A-410B-470B, although any other suitable folding technique may be used, such as stamping all folds and the optional depression in a single step.

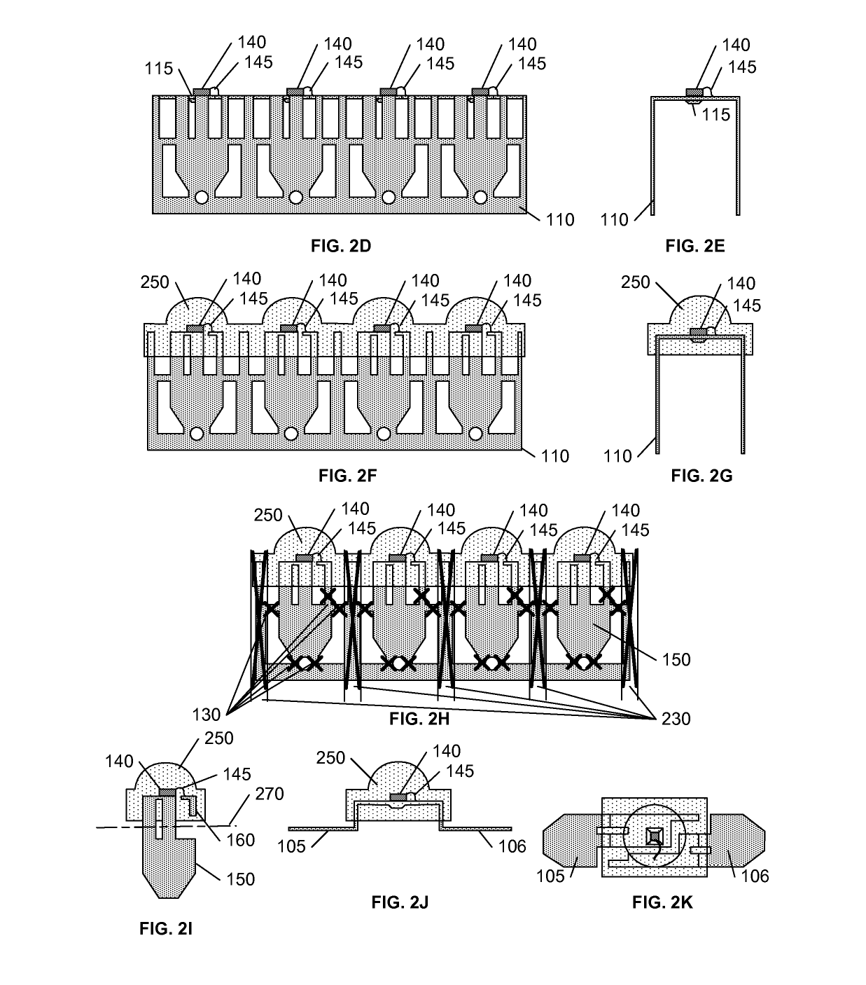

As contrast to the prior art profile of the leadframe 110 at FIG. 2C, the profile of the leadframe 310 at FIG. 4B illustrates a compound folding, such that the contact pads 305, 306 are situated in a plane that is substantially parallel to the surface area 315 upon which the light emitting element 140 is to be situated, which is the desired plane for mounting the fabricated light emitting device on a printed circuit board. The intended application of the packaged light emitting device will determine the required degree of accuracy in the alignment of the planes of the surface area and the contact pads, but generally embodiments of this invention will provide planes that are well within +/−10° of parallel.

Of particular note, as contrast to the prior art leadframe 110, this compound folding of the leadframe 310 is performed before the mounting and encapsulation of the light emitting element 140.

FIG. 4C illustrates the lead frame 310 after mounting of the light emitting element 140, attachment of the bonding wire 145, and encapsulation with an encapsulant 250, which may be silicone or other moldable material. The encapsulant 250 may include wavelength conversion material, such as phosphors or other materials, to achieve a desired color point, or dyes, scattering particles, and so on to achieve a desired optical effect. The encapsulant 250 may be shaped to achieve a desired light output pattern.

For ease of illustration, the light emitting element 140 is illustrated as being visible above the lead frame 310, although in a preferred embodiment, the surface area 315 of the leadframe 310 may be depressed at the locale of the light emitting element 140, to provide the aforementioned reflective cup for reflecting light that may be emitted from the sides of the light emitting element 140.

FIG. 4D illustrates the points (X) 330 for severing the tie-bars of the leadframe 310, and the slice line (X) 332 to provide singulated light emitting devices 300. The tie-bars 380 may be eliminated, or the number reduced, to facilitate the slicing process, provided the resulting leadframe is sufficiently rigid to support the subsequent packaging processes. Alternatively, the slicing may be performed on either side of the tie-bars 380, avoiding the cutting of metal during the slicing process.

Only two devices 300 are illustrated in FIG. 4D; one of skill in the art will recognize that the tie-bars of all of the devices that are on the leadframe 310 will be severed, typically by sawing the entire leadframe 310 along the lines 335A-B.

By appropriate design of the LED metal patterns 301 in the leadframe 310, along with forming the compound folds 410A-B, 470A-B before attaching and embedding the light emitting elements 140, the complexity of the singulation process is significantly reduced, as compared to the prior art process illustrated in FIGS. 2A-2K. And, because the leadframe 310 is pre-formed to have the desired profile of the final product, the packaged light emitting devices are not subject to the stresses associated with the folding process, significantly reducing the stress-induced failures associated with the conventional post-encapsulation folding.

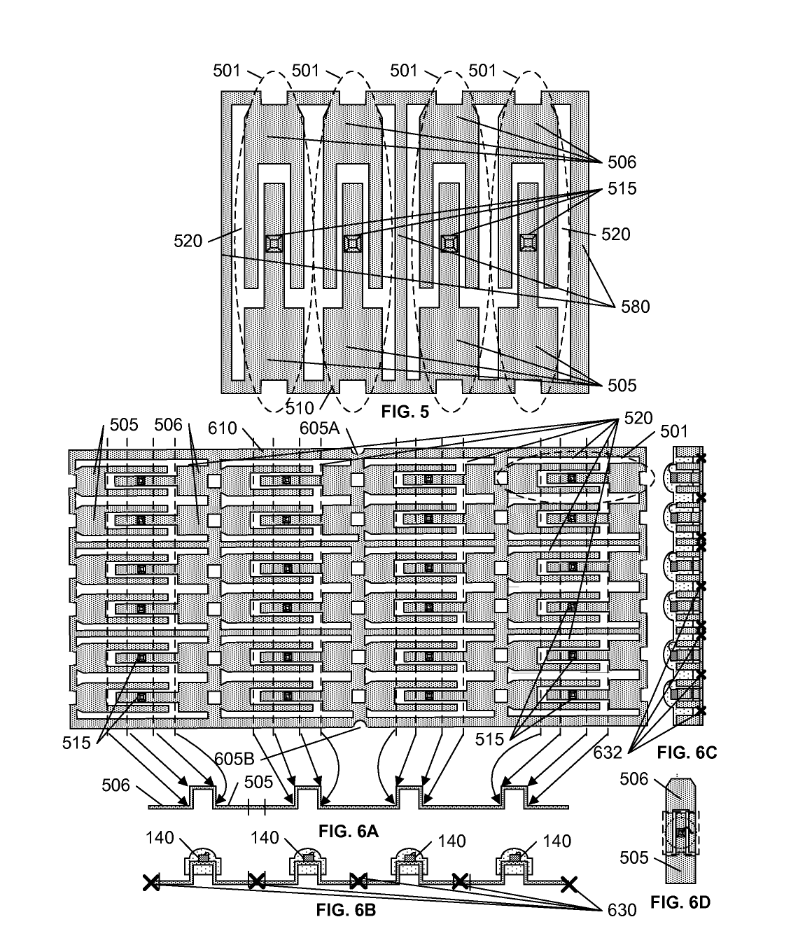

FIG. 5 illustrates an example alternative leadframe 510 with an opening pattern 520 that defines the LED metal patterns for a pair of light emitting devices, each pattern including surface area 515 and contact pads 505, 506. In this example, the tie-bar 580 is situated between pairs of LED metal patterns 501, thereby reducing the number of tie-bars 580 that may need to be sliced.

FIGS. 6A-6D illustrate an example leadframe 610 for fabricating a matrix of light emitting devices. FIG. 6A illustrates both a plan view and a profile view, to illustrate the folding process; FIGS. 6B and 6C illustrate the profiles of the bent leadframe 610 from each axis; FIG. 6D illustrates a plan view of a singulated device.

In this example, the alternative hole pattern 520 of FIG. 5 is replicated in the horizontal and vertical directions, as illustrated in FIG. 6A. This allows for the packaging of an array, or matrix, of light emitting devices at the same time, thereby increasing the throughput of the packaging process, as compared to the conventional process of FIGS. 2A-2K. Alignment notches 605A and 605B facilitate the alignment of the leadframe 610 for placing the array of light emitting elements 140 in each surface area 515 in the surface of the leadframe 610, and for forming the encapsulation above each of these light emitting elements.

Although only a 3×4 {each hole pattern defines two LED metal patterns 501) replication of the hole pattern 520 is illustrated in FIG. 6A, which provides for 24 LED metal patterns (501 in FIG. 5), the matrix form of the leadframe 610 allows for the creation of a hundred or more light emitting structures using a single matrix leadframe.

The vertical dashed lines indicate the fold lines for forming the compound fold that places the contact pads 505, 506 of the LED metal patterns in a plane parallel to the surface area 615 upon which the light emitting elements 140 will subsequently be mounted. The resultant profile is illustrated below the plan view of the leadframe 610.

Light emitting elements 140 are picked and placed upon the surface area 615 of the compound folded leadframe 610, and subsequently encapsulated, as illustrated in FIGS. 6B and 6C. As illustrated in FIG. 6B, each column of LED metal patterns is encapsulated, providing the profile illustrated in FIG. 6C. Slicing along the regions identified by the Xs 630 of FIG. 6B separates the contact pads 505, 506 of adjacent light emitting devices, and slicing along the regions identified by the Xs 632 of FIG. 6C completes the singulation of each of the devices. The sequence of slicing may be performed in any order.

A planar view of the resultant singulated device is illustrated in FIG. 6D.

While the invention has been illustrated and described in detail in the drawings and foregoing description, such illustration and description are to be considered illustrative or exemplary and not restrictive; the invention is not limited to the disclosed embodiments.

For example, it is possible to operate the invention in an embodiment wherein the LED metal patterns are substantially different from the example patterns 301, 501 illustrated in the drawings. Any pattern may be used provided that the pre-folding of the leadframe to place the contact pads in a common plane does not substantially interfere with the isolation of the contact pads from one another, and does not substantially interfere with the singulation process. Placing the tie-bars that need to be removed for this isolation and singulation at the common plane of the contact pads after folding will generally suffice to avoid this interference.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. Any reference signs in the claims should not be construed as limiting the scope.

1. A leadframe comprising:
a plurality of LED metal patterns, each LED metal pattern comprising:
a first plane, the first plane comprising:
a surface area for mounting a light emitting element, and
at least one tie bar,
a pair of contact pads for external coupling to the light emitting element, and
a plurality of at least four folds that are formed so that the contact pads lie in a second plane that is substantially parallel to the surface area for mounting the light emitting element.

2. The leadframe of claim 1, wherein the plurality of LED metal patterns are arrayed in two dimensions.

3. The leadframe of claim 2, wherein the folding of the leadframe is along one of the two dimensions, and includes at least eight fold lines.

4. The leadframe of claim 1, including a light emitting element situated at the surface area of each LED metal pattern.

5. The leadframe of claim 4, wherein each light emitting element includes a pair of electrodes that is coupled to the pair of contact pads.

6. The leadframe of claim 5, including an encapsulant that encapsulates each of the surface areas containing the light emitting elements.

7. The leadframe of claim 6, wherein the encapsulant includes silicone.

8. The leadframe of claim 1, wherein the plurality of LED metal patterns are formed such that singulated LED metal patterns can be obtained by slicing only through the plane of the contact pads.

9. A method comprising:
creating a plurality of LED metal patterns on a leadframe, each LED metal pattern comprising:
a first plane, the first plane comprising:
a surface area for mounting a light emitting element, and
at least one tie bar, and
a pair of contact pads for external coupling to the light emitting element, and
folding the leadframe along at least four fold lines to pre-form the leadframe such that the contact pads lie in a second plane that is substantially parallel to the first plane for mounting the light emitting element, after the folding:
situating each of a plurality of light emitting elements on each of the surface areas, each light emitting element having at least two electrodes,
coupling the at least two electrodes of each light emitting element to the pair of contact pads,
encapsulating the surface areas containing the light emitting elements with an encapsulant, forming a plurality of encapsulated light emitting devices, and
slicing the lead frame to provide a plurality of singulated light emitting devices.

10. The method of claim 9, wherein the plurality of LED metal patterns are arrayed in two dimensions.

11. The method of claim 10, wherein the folding of the leadframe is along one of the two dimensions, and includes at least eight fold lines.

12. The method of claim 9, wherein the encapsulant includes silicone.

13. The method of claim 9, wherein the encapsulant includes a wavelength conversion material.

14. The method of claim 9, including creating a depression at each of the surface areas, and wherein situating the light emitting elements includes situating the light emitting elements in the depression of each surface area.

15. The method of claim 9, wherein the slicing of the leadframe is limited to slicing through the plane of the contact pads.
